(19) United States
(12) Patent Application Publication
(10) Pub. No.: US 2012/0274344 A1
(43) Pub. Date: Nov. 1, 2012

(54) TESTING SYSTEM FOR PRINTED CIRCUIT BOARD

(75) Inventors: XIANG-BIAO CHEN, Wuhan City (CN); SHU-QI WU, Wuhan City (CN); YU-LIN LIU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/240,256

(22) Filed: Sep. 22, 2011

(30) Foreign Application Priority Data
Apr. 26, 2011 (CN) 201110104933.1

(51) Int. Cl. G01R 31/00

(52) U.S. Cl. 324/750.01

(57) ABSTRACT

A test system includes a testing power supply unit which includes a rectifier and filter circuit and a voltage output circuit, a dropping voltage circuit which includes a primary coil and a secondary coil, a PWM regulator, and a control circuit. The rectifier and filter circuit receives an AC voltage and converts the AC voltage into a square wave signal. The primary coil is connected to the rectifier and filter circuit and receives the square wave signal. The secondary coil is connected to the voltage output circuit. The PWM regulator is connected to the primary coil. The PWM regulator generates a pulse signal to turn on and turn off the primary coil periodically. The control circuit is connected to the PWM regulator. The control circuit controls a duty cycle of the pulse signal to adjust time of the primary coil being on in a cycle.

### BACKGROUND

1. Technical Field

The present disclosure relates to a testing system, more particularly to a testing device for testing a printed circuit board.

2. Description of Related Art

After assembling a printed circuit board into an electronic device, an overall test is required to check the functions of the printed circuit board. The test mainly tests for defects such as an open circuit or short circuit, as well as for any substandard connections between the components under normal voltage, overvoltage, or under-voltage conditions. However, many testing systems can not provide a variety of other voltages in testing a printed circuit board.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram view of an embodiment of a testing system for a printed circuit board.

FIG. 2 is a block diagram view of a testing power supply unit of the testing system of FIG. 1.

FIG. 3 is a schematic view of the testing power supply unit of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

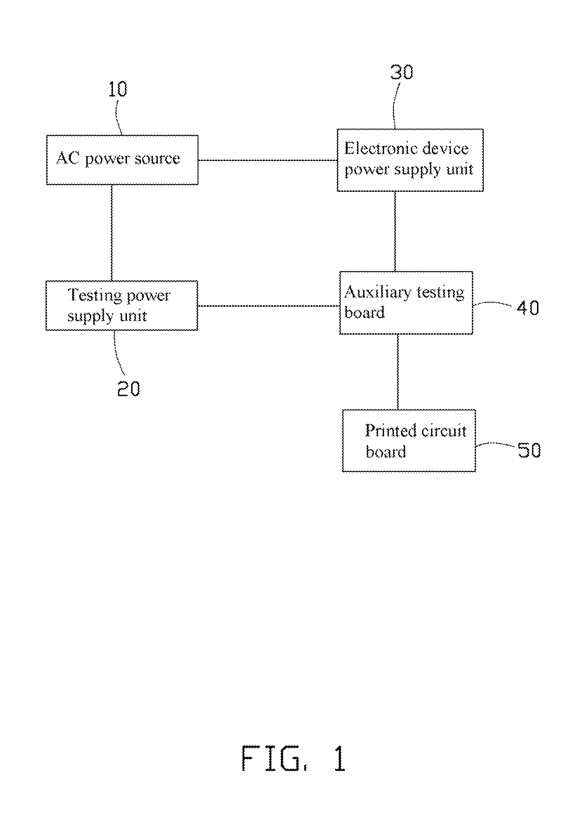

Referring to FIG. 1, a testing system in accordance with an exemplary embodiment includes an alternating current (AC) power source 10, a testing power supply unit 20, an inbuilt electronic device power supply unit 30, an auxiliary testing board 40, and a printed circuit board 50 which is the subject of the test. The electronic device power supply unit 30 and the printed circuit board 50 are both mounted in an electronic device.

The AC power source 10 is connected to the testing power supply unit 20 and to the electronic device power supply unit 30. The AC power source 10 provides an AC voltage to the testing power supply unit 20 and to the electronic device power supply unit 30. The testing power supply unit 20 converts the AC voltage into different direct current (DC) voltages, such as +12 volts (12V), +5V, and +3.3V. The DC voltages may be provided to the printed circuit board 50. The electronic device power supply unit 30 converts the AC voltage into a standby voltage. The electronic device power supply unit 30 supplies a PS-ON signal to the electronic device and the standby voltage may be provided to the electronic device to start up the electronic device.

The auxiliary testing board 40 is connected to the testing power supply unit 20 and the electronic device power supply unit 30. The auxiliary testing board 40 transmits voltages and signals provided by the testing power supply unit 20 and the electronic device power supply unit 30 to the printed circuit board 50.

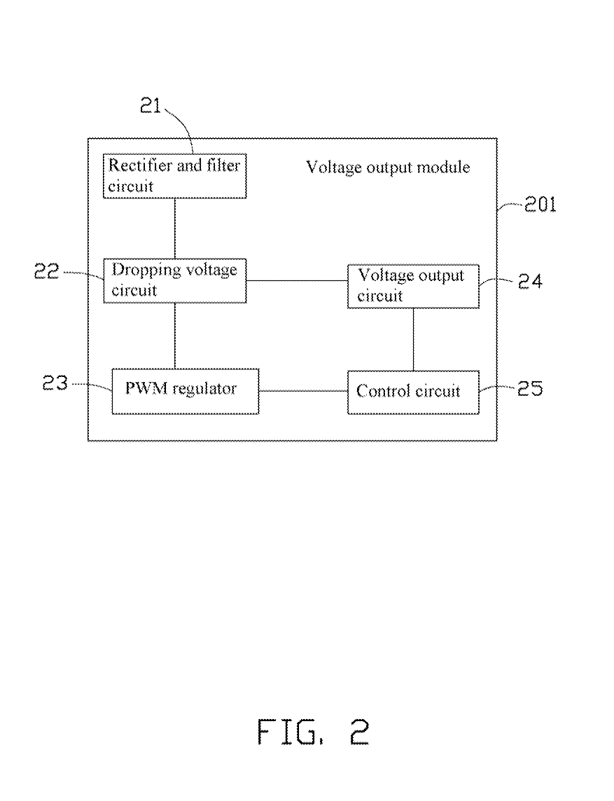

Referring to FIG. 2, the testing power supply unit 20 includes a plurality of voltage output modules 201. Each voltage output module 201 includes a rectifier and filter circuit 21, a dropping voltage circuit 22, a PWM (pulse-width modulation) regulator 23, a voltage output circuit 24, and a control circuit 25.

The rectifier and filter circuit 21 is connected to the AC power source 10 to receive the AC voltage. The rectifier and filter circuit 21 converts the AC voltage into a square wave signal which is symmetrical about zero volts or above zero volts. The dropping voltage circuit 22 receives the square wave signal. The dropping voltage circuit 22 is connected to the PWM regulator 23. The dropping voltage circuit 22 lowers the voltage of the square wave signal according to a pulse signal provided by the PWM regulator 23. The voltage output circuit 24 is connected to the dropping voltage circuit 22 and outputs the dropped voltage to the auxiliary testing board 40. The control circuit 25 is connected to the voltage output circuit 24 and the PWM regulator 23. The control circuit 25 monitors the dropped voltage being output by the voltage output circuit 24 and controls the duty cycle of the pulse signal of the PWM regulator 23.

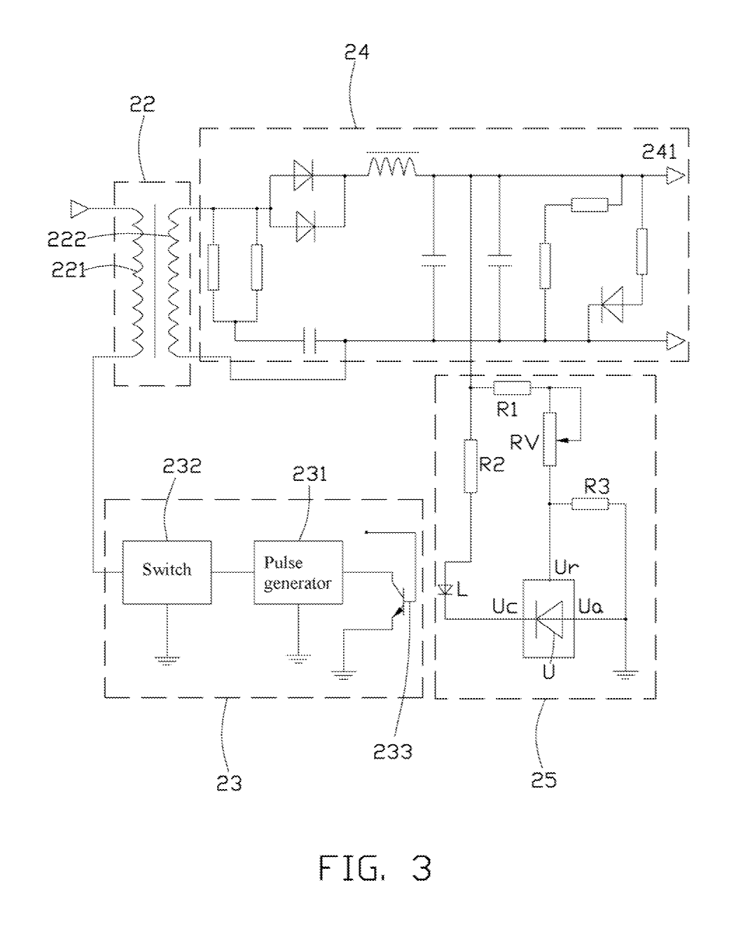

Referring to FIG. 3, the dropping voltage circuit 22 includes a primary coil 221 and a secondary coil 222. A first end of the primary coil 221 is connected to the rectifier and filter circuit 21. A second end of the primary coil 221 is connected to the PWM regulator 23. The secondary coil 222 is connected to the voltage output circuit 24. The voltage output circuit 24 includes an output end 241 which outputs a DC voltage to the auxiliary testing board 40.

The control circuit 25 includes a first resistor R1, a second resistor R2, a third resistor R3, a light-emitting diode L, a variable resistor RV, and a three-terminal adjustable regulator U. The three-terminal adjustable regulator U includes a regulator anode Ua, a regulator cathode Uc, and a reference end Ur. When the voltage value on the reference end Ur is close to a reference voltage, an unsaturated current flows through the regulator anode Ua and the regulator cathode Uc. The value of the unsaturated current increases with an increase of the voltage value on the reference end Ur. The value of the unsaturated current decreases with a decrease of the voltage value on the reference end Ur.

The adjustable terminal of the variable resistor RV is connected to the output end 241 of the voltage output circuit 24 via the first resistor R1. The fixed terminal of the variable resistor RV is connected to ground via the third resistor R3. The light-emitting diode L includes a diode anode and a diode cathode. The diode anode is connected to the output end 241 via the resistor R2. The diode cathode is connected to the regulator cathode Uc. The reference end Ur is connected to the fixed terminal of the variable resistor RV. The regulator anode Ua is connected to ground.

The PWM regulator 23 includes a pulse generator 231, a switch 232, and a opto-electronic coupler 233. The opto-electronic coupler 233 is located adjacent to the light-emitting diode L and senses light emitted by the light-emitting diode L. The opto-electronic coupler 233 includes a first coupler end and a second coupler end. The first coupler end is connected to ground. The second coupler end is connected to the pulse generator 231. The primary coil 221 is connected to ground via the switch 232. The pulse generator 231 is connected to the switch 232 and turns the switch 232 on and off at a certain frequency. When the light-emitting diode L is brightly illuminated, the current flowing through the opto-electronic coupler 233 is large. So, the duty cycle of the pulse generated by the pulse generator 231 is small, that is, the “on” time of the switch is small. The dropping voltage circuit 22 works a short during time in a cycle. Therefore, the secondary coil 222 receives a small amount of energy in one cycle, which causes only a small voltage to be output by the voltage output circuit 24. Vice versa, when the light-emitting diode L emits a weak light, the voltage outputted by the voltage output circuit 24 is large.

Referring to FIGS. 1 to 3, when the testing system is working, the AC power source 10 provides an AC voltage to the rectifier and filter circuit 21. The rectifier and filter circuit 21 converts the AC voltage into a square wave signal which is sent to the primary coil 221. The secondary coil 222 generates a corresponding voltage. The output end 241 outputs a DC voltage to the auxiliary testing board 40. The auxiliary testing board 40 forwards the DC voltage to the printed circuit board 50 to test the printed circuit board 50.

When an increase in the DC voltage being output by the output end 241 is needed, the adjustable terminal of the variable resistor RV is moved to increase the resistance of the variable resistor RV. Thereby, the voltage on the reference end Ur decreases. The amount of current flowing into the light-emitting diode L decreases, and the light emitted by the light-emitting diode L becomes weaker. As a result, the DC voltage output at the output end 241 increases.

When a decrease in the DC voltage being output by the output end 241 is required, the adjustable terminal of the variable resistor RV is moved to decrease the resistance of the variable resistor RV. Thereby, the voltage on the reference end Ur increases. The amount of current flowing through the light-emitting diode L increases.

The light being emitted by the light-emitting diode L becomes brighter. So, the DC voltage output of the output end 241 becomes smaller.

In the above test system, the adjustment of the DC voltage output of simply by adjusting the variable resistor RV is very convenient.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A test system for a printed circuit board, comprising:
a testing power supply unit comprising a rectifier and filter circuit and a voltage output circuit, the rectifier and filter circuit adapted to receive an AC voltage, and the rectifier and filter circuit adapted to convert the AC voltage into a square wave signal;
a dropping voltage circuit comprising a primary coil and a secondary coil, the primary coil connected to the rectifier and filter circuit, the primary coil adapted to receive the square wave signal, and the secondary coil is connected to the voltage output circuit;
a PWM regulator connected to the primary coil, and the PWM regulator adapted to generate a pulse signal to turn on and turn off the primary coil periodically; and
a control circuit connected to the PWM regulator, the control circuit adapted to control a duty cycle of the pulse signal to adjust a during time of the primary coil being on in a cycle, and the primary coil adapted to transmit corresponding energy to the secondary coil according the during time.

2. The test system of claim 1, wherein the control circuit comprises a light-emitting diode, the PWM regulator comprises an opto-electronic coupler and a pulse generator which is adapted to generate the pulse signal, the opto-electronic coupler is connected to the pulse generator, the opto-electronic coupler is located adjacent the light-emitting diode and senses light emitted by the light-emitting diode, and a first current flowing through the opto-electronic coupler is adjusted by the brightness of the light emitted by the light-emitting diode, and the duty cycle of the pulse signal is adjusted by the first current.

3. The test system of claim 2, wherein the control circuit comprises a three-terminal adjustable regulator which comprises a regulator anode, a regulator cathode, and a reference end, the light-emitting diode comprises a diode anode and a diode cathode, the regulator cathode is connected to the diode cathode, the regulator anode is connected to ground, and a voltage value on the reference end is adapted to adjust a second current which flows through the regulator anode and the regulator cathode.

4. The test system of claim 3, wherein the voltage output circuit comprises an output end which is adapted to output an DC voltage, the reference end is connected to the output end via a variable resistor.

5. The test system of claim 4, wherein the variable resistor comprises an adjustable terminal and a fixed terminal, the fixed terminal is connected to the reference end, and the adjustable terminal is connected to the output end via a first resistor.

6. The test system of claim 5, wherein the reference end is connected to ground via a third resistor.

7. The test system of claim 3, wherein the diode anode is connected to the voltage output circuit via a second resistor.

8. The test system of claim 1, wherein the PWM regulator comprises a switch, the primary coil is connected to ground via the switch, and the pulse signal is supplied to the switch to turn on and turn off the switch periodically.

9. A test system for testing a printed circuit board, comprising:
a rectifier and filter circuit adapted to receive an AC voltage and adapted to convert the AC voltage into a square wave signal;
a dropping voltage circuit connected to the rectifier and filter circuit, and the dropping voltage circuit adapted to receive the square wave signal;
a voltage output circuit connected to the dropping voltage circuit;
a PWM regulator connected to the dropping voltage circuit, and the PWM regulator adapted to generate a pulse signal to turn on and turn off the dropping voltage circuit periodically; and
a control circuit connected to the PWM regulator, and the control circuit adapted to control a duty cycle of the pulse signal to adjust a during time of the dropping voltage circuit being on in a cycle.

10. The test system of claim 9, wherein the dropping voltage circuit comprises a primary coil and a secondary coil, the primary coil is connected to the rectifier and filter circuit to receive the square wave signal, and the secondary coil is connected to the voltage output circuit.

11. The test system of claim 10, wherein the control circuit comprises a light-emitting diode, the PWM regulator comprises an opto-electronic coupler and a pulse generator which is adapted to generate the pulse signal, the opto-electronic coupler is connected to the pulse generator, the opto-electronic coupler is located adjacent the light-emitting diode and senses light emitted by the light-emitting diode, a first current flowing through the opto-electronic coupler is adjusted by the brightness of the light emitted by the light-emitting diode, and the duty cycle of the pulse signal is adjusted by the first current.

12. The test system of claim 11, wherein the control circuit comprises an three-terminal adjustable regulator which comprises a regulator anode, a regulator cathode, and a reference end, the light-emitting diode comprises a diode anode and a diode cathode, the regulator cathode is connected to the diode cathode, the regulator anode is connected to ground, and a voltage value on the reference end is adapted to adjust a second current which flows through the regulator anode and the regulator cathode.

13. The test system of claim 12, wherein the voltage output circuit comprises an output end which is adapted to output an DC voltage, the reference end is connected to the output end via a variable resistor.

14. The test system of claim 13, wherein the variable resistor comprises an adjustable terminal and a fixed terminal, the fixed terminal is connected to the reference end, the adjustable terminal is connected to the output end via a first resistor.

15. The test system of claim 14, wherein the reference end is connected to ground via a third resistor.

16. The test system of claim 12, wherein the diode anode is connected to the voltage output circuit via a second resistor.

17. The test system of claim 10, wherein the PWM regulator comprises a switch, the primary coil is connected to ground via the switch, and the pulse signal is supplied to the switch to turn on and turn off the switch periodically.
